(19) United States
(12) Patent Application Publication
(10) Pub. No.: US 2010/0167556 A1
(43) Pub. Date: Jul. 1, 2010

(54) THREE DEGREE OF MOVEMENT MOVER AND METHOD FOR CONTROLLING A THREE DEGREE OF MOVEMENT MOVER

(75) Inventors: Masahiro Totsu, Kamagaya (JP); Michael B. Binnard, Belmont, CA (US); Scott Coakley, Belmont, CA (US)

Correspondence Address: Roeder & Broder LLP, 5560 Chelsea Avenue, La Jolla, CA, 92037, US

(73) Assignee: Nikon Corporation, Chiyoda-ku (JP)

(21) Appl. No.: 12/596,569

(22) PCT Filed: Apr. 16, 2008
(86) PCT No.: PCT/US08/04896

§ 371 Date: Mar. 4, 2010

Related U.S. Application Data
(63) Continuation of application No. 61/038,931, filed on Mar. 24, 2008.
(60) Provisional application No. 60/925,334, filed on Apr. 19, 2007.

(51) Int. Cl. H01L 21/26; G03B 27/58; H02K 41/02; H02P 7/285; H05K 13/00

(52) U.S. Cl. 438/795; 355/77; 355/72; 310/12.05; 318/135; 29/592.1; 257/E21.328

(57) ABSTRACT

A mover (344) moving a stage (238) along a first axis and about a second axis includes a magnetic component (454), and a conductor component (456). The magnetic component (454) includes one or more magnets (454D) that are surrounded by a magnetic field. The conductor component (456) is positioned near the magnetic component (454) in the magnetic field. Further, the conductor component (456) interacts with the magnetic component (454) when current is directed to the conductor component (456) to generate a controlled force along the first axis, and a controlled moment about the second axis. Additionally, the conductor component (456) interacts with the magnetic component (454) to generate a controlled force along a third axis that is perpendicular to the first axis and the second axis when current is directed to the conductor component (456).

### RELATED APPLICATION

The application claims priority on (i) Provisional Application Ser. No. 60/925,334 filed on Apr. 19, 2007, entitled “THREE DEGREE OF FREEDOM LINEAR MOTOR AND A MEANS OF CONTROLLING IT”, and Provisional Application Ser. No. 61/038,931 filed on Mar. 24, 2008, entitled “THREE DEGREE OF MOVEMENT MOVER AND METHOD FOR CONTROLLING A THREE DEGREE OF MOVEMENT MOVER.” As far as is permitted, the contents of Provisional Application Ser. Nos. 60/925,334 and 61/038,931 are incorporated herein by reference.

### BACKGROUND

Exposure apparatuses for semiconductor processing are commonly used to transfer images from a reticle onto a semiconductor wafer during semiconductor processing. A typical exposure apparatus includes an illumination source, a reticle stage assembly that positions a reticle, an optical assembly, a wafer stage assembly that positions a semiconductor wafer, a measurement system, and a control system. The features of the images transferred onto the wafer from the reticle are extremely small. Accordingly, the precise positioning of the wafer and the reticle is critical to the manufacturing of high quality wafers.

One type of stage assembly includes a stage base, a stage that retains the wafer or reticle, and one or more movers that move the stage and the wafer or the reticle. One type of mover is a three phase linear motor that includes a pair of spaced apart magnet arrays that are surrounded by a magnetic field and a conductor array positioned between the magnet arrays. A three phase electrical current is directed to the conductor array. The electrical current supplied to the conductor array generates an electromagnetic field that interacts with the magnetic field of the magnet arrays. This generates a controlled force that can be used to move the conductor array relative to the magnet arrays along a first axis.

Unfortunately, electrical current supplied to the conductor array also produces uncontrolled forces along a second axis (side to side) that is orthogonal to the first axis, along a third axis (up or down) that is orthogonal to the first and second axes, and about the second axis. These forces can cause disturbances that are transferred to other components of the exposure apparatus and positional error.

### SUMMARY

The present invention is directed to a mover that moves a stage along a first axis. The mover includes a magnetic component, and a conductor component. The magnetic component includes a plurality of magnets that are surrounded by a magnetic field. Further, the magnetic component defines a magnetic gap. The conductor component is positioned near the magnetic component in the magnetic gap. In certain embodiments, the conductor component interacts with the magnetic component when current is directed to the conductor component to generate a controlled force along the first axis, a controlled force about a second axis that is perpendicular to the first axis and a controlled moment along a third axis that is perpendicular to both the first axis and the second axis. With this design, the mover can be controlled to (i) cancel any undesired pitching moments (pitching disturbance) about the second axis, or (ii) generate a non-zero pitching moment about the second axis to accurately position the stage. As a result thereof, the mover can be used to position and move the stage with improved accuracy.

Additionally, in certain embodiments, the conductor component interacts with the magnetic component to generate a controlled force along a third axis that is perpendicular to the first axis and the second axis when current is directed to the conductor component.

In one embodiment, the conductor component includes a first array of conductors, and a second array of conductors that are positioned adjacent to the first array along a third axis that is perpendicular to the first axis. Further, the first array is shifted relative to the second array along the first axis. For example, each of the conductor arrays has a coil pitch, and the first array can be shifted approximately one quarter of a coil pitch along the first axis from the second array.

Further, the present invention is also directed to a stage assembly, an exposure apparatus, a method for moving and controlling a stage, a method for manufacturing an exposure apparatus, and a method for manufacturing an object or a wafer.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a schematic illustration of an exposure apparatus having features of the present invention;

FIG. 2A is a simplified top perspective view of a stage assembly having features of the present invention;

FIG. 2B is a simplified end view of the stage assembly of FIG. 2A;

FIG. 3A is a simplified end view of another embodiment of the stage assembly;

FIG. 3B is a simplified end view of yet another embodiment of the stage assembly;

FIG. 4A is a simplified cut-away view of a portion of a mover having features of the present invention;

FIG. 4B is a perspective view of a portion of the mover of FIG. 4A;

FIG. 5A is a chart that illustrates pitching moments created by a first mover;

FIG. 5B is a chart that illustrates pitching moments created by another embodiment of the mover;

FIG. 6A is a perspective view and FIG. 6B is a top plan view of another embodiment of a stage assembly having features of the present invention;

FIG. 6C is a side view of a portion of the stage assembly of FIGS. 6A and 6B;

FIG. 7 illustrates still another embodiment of a stage assembly having features of the present invention;

FIG. 8 illustrates yet another embodiment of a stage assembly having features of the present invention;

FIG. 9A is a flow chart that outlines a process for manufacturing a device in accordance with the present invention; and

FIG. 9B is a flow chart that outlines device processing in more detail.

### DESCRIPTION

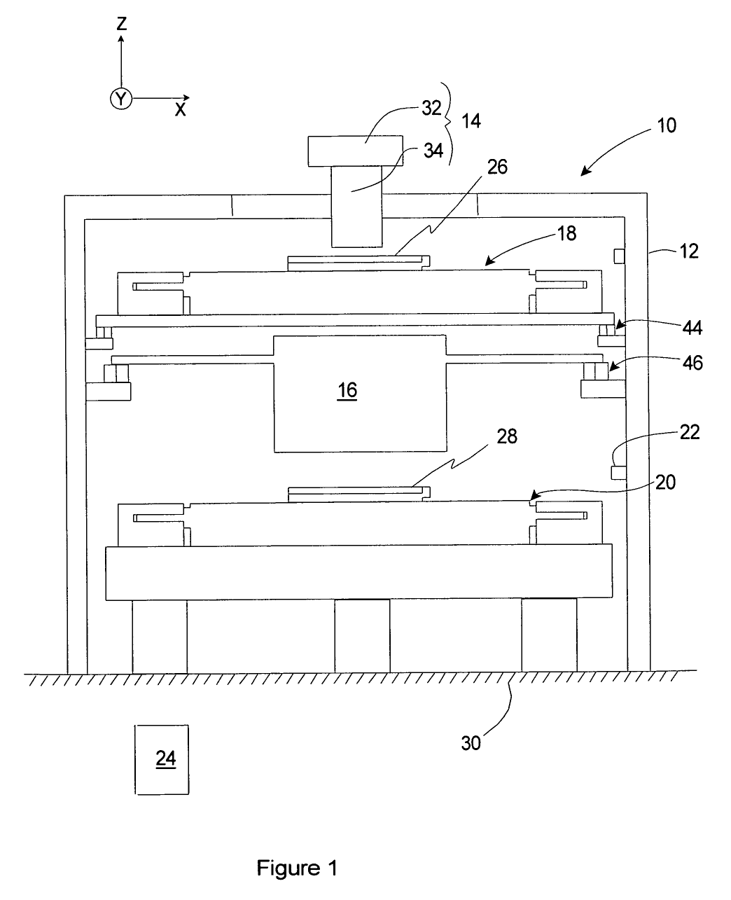

FIG. 1 is a schematic illustration of a precision assembly, namely an exposure apparatus 10 having features of the present invention. The exposure apparatus 10 includes an apparatus frame 12, an illumination system 14 (irradiation apparatus), an optical assembly 16, a reticle stage assembly 18, a wafer stage assembly 20, a measurement system 22, and a control system 24. The design of the components of the exposure apparatus 10 can be varied to suit the design requirements of the exposure apparatus 10.

As an overview, in certain embodiments, one or both of the stage assemblies 18, 20 are uniquely designed to move and position a device with improved accuracy. More specifically, in certain embodiments, one or both stage assemblies 18, 20 includes a linear type motor which can be controlled to independently generate controllable forces along a Y axis, along a Z axis, and about an X axis. This allows for the cancellation of undesired ripple in the forces along the Y axis, along the Z axis, and about the X axis; and/or the active generation of non-zero forces along the Y axis, along the Z axis, and/or about the X axis to accurately position the device. As a result thereof, the linear type motors can position a stage with improved accuracy, and the exposure apparatus 10 can be used to manufacture higher density wafers.

A number of Figures include an orientation system that illustrates the X axis, the Y axis that is orthogonal to the X axis and the Z axis that is orthogonal to the X and Y axes. It should be noted that any of these axes can also be referred to as the first, second, and/or third axes.

The exposure apparatus 10 is particularly useful as a lithographic device that transfers a pattern (not shown) of an integrated circuit from a reticle 26 onto a semiconductor wafer 28. The exposure apparatus 10 mounts to a mounting base 30, e.g., the ground, a base, or floor or some other supporting structure.

There are a number of different types of lithographic devices. For example, the exposure apparatus 10 can be used as a scanning type photolithography system that exposes the pattern from the reticle 26 onto the wafer 28 with the reticle 26 and the wafer 28 moving synchronously. In a scanning type lithographic device, the reticle 26 is moved perpendicularly to an optical axis of the optical assembly 16 by the reticle stage assembly 18 and the wafer 28 is moved perpendicularly to the optical axis of the optical assembly 16 by the wafer stage assembly 20. Scanning of the reticle 26 and the wafer 28 occurs while the reticle 26 and the wafer 28 are moving synchronously.

Alternatively, the exposure apparatus 10 can be a step-and-repeat type photolithography system that exposes the reticle 26 while the reticle 26 and the wafer 28 are stationary. In the step and repeat process, the wafer 28 is in a constant position relative to the reticle 26 and the optical assembly 16 during the exposure of an individual field. Subsequently, between consecutive exposure steps, the wafer 28 is consecutively moved with the wafer stage assembly 20 perpendicularly to the optical axis of the optical assembly 16 so that the next field of the wafer 28 is brought into position relative to the optical assembly 16 and the reticle 26 for exposure. Following this process, the images on the reticle 26 are sequentially exposed onto the fields of the wafer 28, and then the next field of the wafer 28 is brought into position relative to the optical assembly 16 and the reticle 26.

However, the use of the exposure apparatus 10 provided herein is not limited to a photolithography system for semiconductor manufacturing. The exposure apparatus 10, for example, can be used as an LCD photolithography system that exposes a liquid crystal display device pattern onto a rectangular glass plate or a photolithography system for manufacturing a thin film magnetic head. Further, the present invention can also be applied to a proximity photolithography system that exposes a mask pattern from a mask to a substrate with the mask located close to the substrate without the use of a lens assembly.

The apparatus frame 12 is rigid and supports the components of the exposure apparatus 10. The apparatus frame 12 illustrated in FIG. 1 supports the reticle stage assembly 18, the optical assembly 16 and the illumination system 14 above the mounting base 30.

The illumination system 14 includes an illumination source 32 and an illumination optical assembly 34. The illumination source 32 emits a beam (irradiation) of light energy. The illumination optical assembly 34 guides the beam of light energy from the illumination source 32 to the optical assembly 16. The beam illuminates selectively different portions of the reticle 26 and exposes the wafer 28. In FIG. 1, the illumination source 32 is illustrated as being supported above the reticle stage assembly 18. Typically, however, the illumination source 32 is secured to one of the sides of the apparatus frame 12 and the energy beam from the illumination source 32 is directed to above the reticle stage assembly 18 with the illumination optical assembly 34.

The illumination source 32 can be a g-line source (436 nm), an i-line source (365 nm), a KrF excimer laser (248 nm), an ArF excimer laser (193 nm), a F₂ laser (157 nm), or an EUV source (13.5 nm). Alternatively, the illumination source 32 can generate charged particle beams such as an x-ray or an electron beam. For instance, in the case where an electron beam is used, thermionic emission type lanthanum hexaboride (LaB₆) or tantalum (Ta) can be used as a cathode for an electron gun. Furthermore, in the case where an electron beam is used, the structure could be such that either a mask is used or a pattern can be directly formed on a substrate without the use of a mask.

The optical assembly 16 projects and/or focuses the light passing through the reticle 26 to the wafer 28. Depending upon the design of the exposure apparatus 10, the optical assembly 16 can magnify or reduce the image illuminated on the reticle 26. The optical assembly 16 need not be limited to a reduction system. It could also be a 1× or magnification system.

When far ultra-violet rays such as the excimer laser is used, glass materials such as quartz and fluorite that transmit far ultra-violet rays can be used in the optical assembly 16. When the F₂ type laser or x-ray is used, the optical assembly 16 can be either catadioptric or refractive (a reticle should also preferably be a reflective type), and when an electron beam is used, electron optics can consist of electron lenses and deflectors. The optical path for the electron beams should be in a vacuum.

Also, with an exposure device that employs EUV radiation (EUV) of wavelength 13.5 nm or lower, use of the catadioptric type optical system can be considered. For EUV the entire optical path should be in a vacuum. Examples of the catadioptric type of optical system include the disclosure Japan Patent Application Disclosure No. 8-171054 published in the Official Gazette for Laid-Open Patent Applications and its counterpart U.S. Pat. No. 5,668,672, as well as Japan Patent Application Disclosure No. 10-20195 and its counterpart U.S. Pat. No. 5,835,275. In these cases, the reflecting optical device can be a catadioptric optical system incorporating a beam splitter and concave mirror. Japan Patent Application Disclosure No. 8-334695 published in the Official Gazette for Laid-Open Patent Applications and its counterpart U.S. Pat. No. 5,689,377 as well as Japan Patent Application Disclosure No. 10-3039 and its counterpart U.S. Patent Application Ser. No. 873,605 (Application Date: Jun. 12, 1997) also use a reflecting-refracting type of optical system incorporating a concave mirror, etc., but without a beam splitter, and can also be employed with this invention. As far as is permitted, the disclosures in the above-mentioned U.S. patents, as well as the Japan patent applications published in the Official Gazette for Laid-Open

Patent Applications are incorporated herein by reference.

The reticle stage assembly 18 holds and positions the reticle 26 relative to the optical assembly 16 and the wafer 28. Somewhat similarly, the wafer stage assembly 20 holds and positions the wafer 28 with respect to the projected image of the illuminated portions of the reticle 26.

Further, in photolithography systems, when linear motors (see U.S. Pat. Nos. 5,623,853 or 5,528,118) are used in a wafer stage or a mask stage, the linear motors can be either an air levitation type employing air bearings or a magnetic levitation type using Lorentz force or reactance force. Additionally, the stage could move along a guide, or it could be a guideless type stage that uses no guide. As far as is permitted, the disclosures in U.S. Pat. Nos. 5,623,853 and 5,528,118 are incorporated herein by reference.

Alternatively, one of the stages could be driven by a planar motor, which drives the stage by an electromagnetic force generated by a magnet unit having two-dimensionally arranged magnets and an armature coil unit having two-dimensionally arranged coils in facing positions. With this type of driving system, either the magnet unit or the armature coil unit is connected to the stage and the other unit is mounted on the moving plane side of the stage.

Movement of the stages as described above generates reaction forces that can affect performance of the photolithography system. Reaction forces generated by the wafer (substrate) stage motion can be mechanically transferred to the floor (ground) by use of a frame member as described in U.S. Pat. No. 5,528,100 and published Japanese Patent Application Disclosure No. 8-136475. Additionally, reaction forces generated by the reticle (mask) stage motion can be mechanically transferred to the floor (ground) by use of a frame member as described in U.S. Pat. No. 5,874,820 and published Japanese Patent Application Disclosure No. 8-330224. As far as is permitted, the disclosures in U.S. Pat. Nos. 5,528,100 and 5,874,820 and Japanese Patent Application Disclosure No. 8-330224 are incorporated herein by reference.

The measurement system 22 monitors movement of the reticle 26 and the wafer 28 relative to the optical assembly 16 or some other reference. With this information, the control system 24 can control the reticle stage assembly 18 to precisely position the reticle 26 and the wafer stage assembly 20 to precisely position the wafer 28. For example, the measurement system 22 can utilize multiple laser interferometers, encoders, and/or other measuring devices.

The control system 24 is connected to the reticle stage assembly 18, the wafer stage assembly 20, and the measurement system 22. The control system 24 receives information from the measurement system 22 and controls the stage assemblies 18, 20 to precisely position the reticle 26 and the wafer 28. The control system 24 can include one or more processors and circuits.

A photolithography system (an exposure apparatus) according to the embodiments described herein can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. Needless to say, there is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

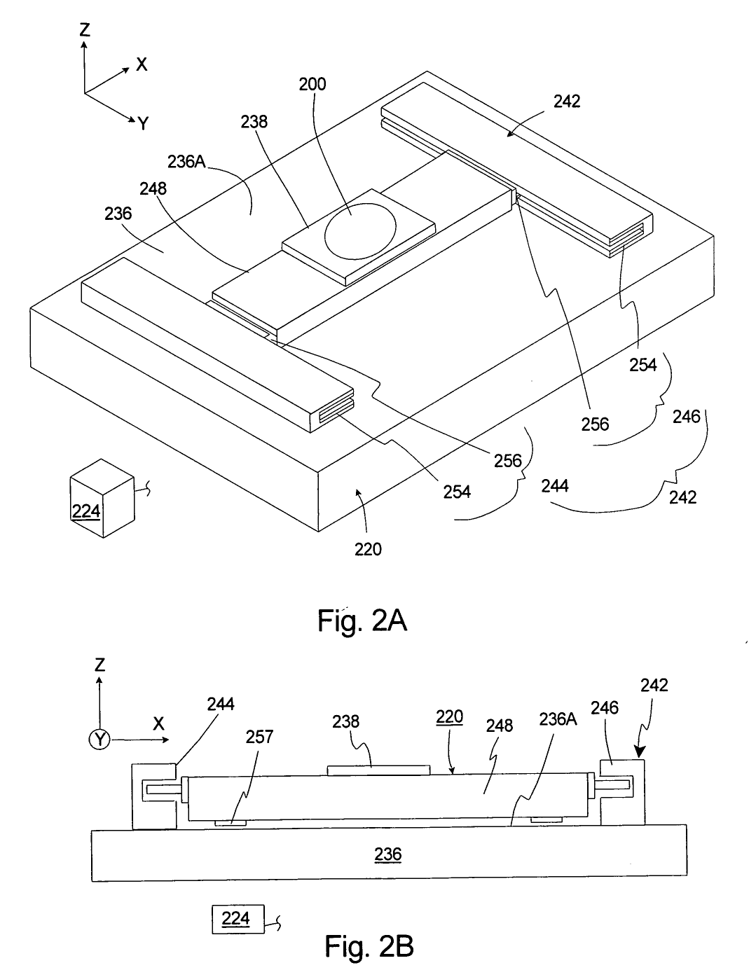

FIG. 2A is a simplified top perspective of a control system 224 and one embodiment of a stage assembly 220 that is used to position a work piece 200. For example, the stage assembly 220 can be used as the wafer stage assembly 20 in the exposure apparatus 10 of FIG. 1. In this embodiment, the stage assembly 220 would position the wafer 28 (illustrated in FIG. 1) during manufacturing of the semiconductor wafer 28. Alternatively, the stage assembly 220 can be used to move other types of work pieces 200 during manufacturing and/or inspection, to move a device under an electron microscope (not shown), or to move a device during a precision measurement operation (not shown). For example, the stage assembly 220 could be designed to function as the reticle stage assembly 18 illustrated in FIG. 1.

In FIG. 2A, the stage assembly 220 includes a stage base 236, a stage 238, and a stage mover assembly 242. The size, shape, and design of each these components can be varied. The control system 224 precisely controls the stage mover assembly 242 to precisely position the work piece 200.

In FIG. 2A, the stage base 236 supports some of the components of the stage assembly 220 and guides the movement of the stage 238 along the X axis, along the Y axis and about the Z axis. In certain embodiments, the stage base 236 is generally rectangular shaped and includes a generally planar guide surface 236A that directly or indirectly supports and/or guides movement of the stage 238. In this embodiment, the guide surface 236A extends along Y and X axes.

The stage 238 retains the work piece 200. In one embodiment, the stage 238 is generally rectangular shaped and includes a chuck (not shown) for holding the work piece 200.

The stage mover assembly 242 moves and positions the stage 238. In FIG. 2A, the stage mover assembly 242 includes a first mover 244, a spaced apart second mover 246, and a connector bar 248 that extends between the movers 244, 246.

The design of each mover 244, 246 can be varied to suit the movement requirements of the stage mover assembly 242. In FIG. 2A, each of the movers 244, 246 includes a first mover component 254 and a second mover component 256 that interacts with the first mover component 254. In this embodiment, each of the movers 244, 246 is a uniquely designed and controlled linear motor, and one of the mover components 254, 256 is a magnetic component that includes one or more magnets, and one of the mover components 256, 254 is a conductor component that includes one or more conductors, e.g. coils. In FIG. 2A, the first mover component 254 is the magnetic component and the second mover component 256 is the conductor component. Alternatively, the first mover component 254 can be the conductor component and the second mover component 256 can be the magnetic component.

In FIG. 2A, for each mover 244, 246, the first mover component 254 is coupled to the stage base 236 and the second mover component 256 is secured to the connector bar 248. Alternatively, for example, the first mover component 254 of one or more of the movers 244, 246 can be secured to a counter/reaction mass or a reaction frame (not shown).

The connector bar 248 supports the stage 238 and is moved by the movers 244, 246. In FIG. 2A, the connector bar 248 is somewhat rectangular beam shaped.

FIG. 2B is a simplified end view of the stage assembly 220 of FIG. 2A. In this embodiment, the stage assembly 220 includes one or more bearings 257 that maintain the connector bar 248 (and the stage 238) spaced apart along the Z axis relative to the guide surface 236A of the stage base 236, and allows for motion of the connector bar 248 (and the stage 238) along the Y axis and about the Z axis relative to the stage base 236. In this embodiment, the bearings 257 inhibit motion of the connector bar 248 (and the stage 238) along the Z axis, about the X axis, and about the Y axis. Each of the bearing 257, for example, can be a vacuum preload type fluid bearing, an electro-magnetic type bearing, or a roller type assembly.

It should be noted that vacuum preload type fluid bearings 257 (and other types of bearings) are not infinitely stiff. Thus, any forces along the Z axis, about the X axis, and about the Y axis generated by the stage mover assembly 242 or some other source can cause some movement of the connector bar 248 and the stage 238.

In FIG. 2B, the stage mover assembly 242 (i) moves and positions the stage 238 along the Y axis, and about the Z axis and (ii) reduces disturbance forces along the Z axis, about the X axis, and about the Y axis. In this embodiment, for example, the control system 224 can direct current to each of the movers 244, 246 to generate independently controlled forces along the Y axis, along the Z axis, and about the X axis. This allows for the cancellation of undesired ripple in the forces along the Y axis, along the Z axis, and about the X axis. For example, the movers 244, 246 can be controlled to cancel any forces along the Z axis and about the X axis to maintain the position of the stage 238 along the Z axis and about the X axis. Stated in another fashion, the control system 224 can direct current to each of the movers 244, 246 so that the force along the Z axis and the force about the X axis generated by each of the movers 244, 246 is zero. This allows for more accurate positioning of the stage 238.

Moreover, the force from both movers along the Z axis can be controlled to control the rolling moment applied to the stage about the Y axis.

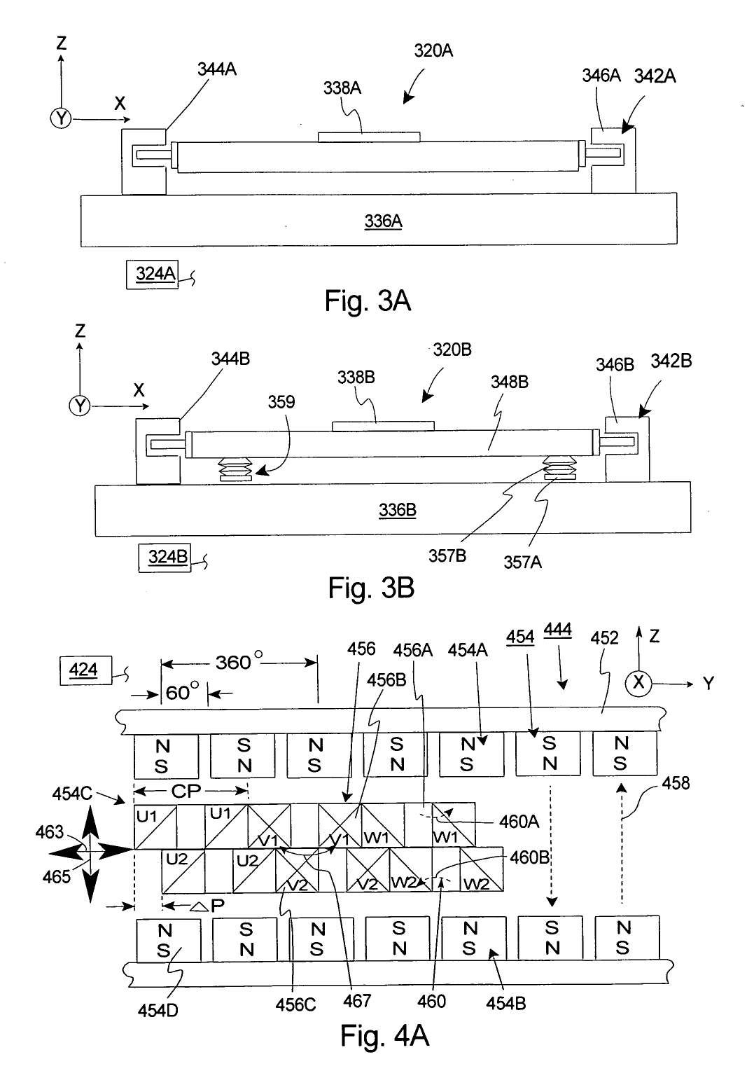

FIG. 3A is a simplified end view of another embodiment of the stage assembly 320A. In this embodiment, the stage mover assembly 342A (i) moves and positions the stage 338A along the Y axis, about the Z axis, along the Z axis, about the X axis, and about the Y axis. In this embodiment for example, the control system 324A directs current to each of the movers 344A, 346A to generate independently controlled forces along a Y axis, along a Z axis, and about an X axis. This allows for the active generation of non-zero forces along the Y axis, along the Z axis, and/or about the X axis to accurately position or maintain the position of the stage 338A along the Y axis, along the Z axis, and about the X axis. Further, by independently controlling the movers 344A, 346A, the position of the stage 338A about the Z axis and about the Y axis can be adjusted. In certain embodiments, another actuator or guide bearing (not shown) can be used to control the position along the X axis.

In FIG. 3A, stage mover assembly 342A electromagnetically supports the stage 338A above the stage base 336A.

FIG. 3B is a simplified end view of yet another embodiment of the stage assembly 320B. In this embodiment, the stage mover assembly 342B moves and positions the stage 338B along the Y axis, about the Z axis, along the Z axis, about the X axis, and about the Y axis. More specifically, in this embodiment, the control system 324B directs current to each of the movers 344B, 346B to generate independently controllable forces along a Y axis, along a Z axis, and about an X axis. This allows for the active generation of non-zero forces along the Y axis, along the Z axis, and/or about the X axis to accurately position the stage 338B along the Y axis, along the Z axis, and about the X axis. Further, by independently controlling the movers 344B, 346B, the position of the stage 338B about the Z axis and about the Y axis can be adjusted.

In FIG. 3B, at least a portion of the weight of the connector bar 348B, the stage 338B, and the work piece (not shown in FIG. 3B) is supported relative to the stage base 336B with one or more support bearings 359. In this embodiment, for example, the one or more support bearings 359 can support the dead weight of the connector bar 348B, the stage 338B, and the work piece while allowing the movers 344B, 346B to move and precisely position these components along the Z axis, about the X axis, and about the Y axis. Further, because the dead weight of these components is supported by the support bearings 359, the movers 344B, 346B do not have to support these components and the movers 344B, 346B are used for fine positional control along the Z axis and about the X axis. This reduces the amount of power consumed by the movers 344B, 346B and the amount of heat generated by the movers 344B, 346B.

In one non-exclusive embodiment, each of the support bearings 359 can include a fluid bearing pad 357A that creates a vacuum preload type fluid bearing that supports the bearing pad 357A relative to the stage base 336B, and a fluid bellows 357B that flexible connects the bearing pad 357A to the connector bar 348B. Alternatively, the bearing pad 357A can be replaced with another type of fluid bearing, a magnetic type bearing, or a roller type assembly and/or the fluid bellows 357B can be replaced with another type of flexible connector.

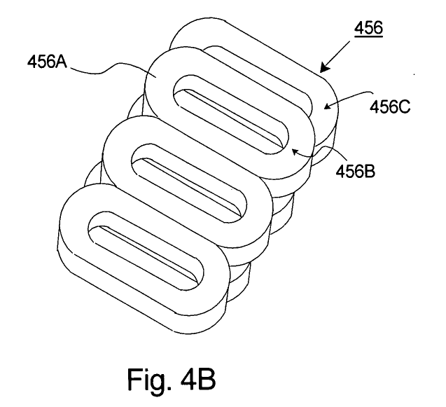

FIG. 4A is a simplified cut-away view of one embodiment of a portion of a mover 444 that can be used as the first mover 244 or the second mover 246 in FIG. 2A, or for another usage. In this embodiment, the mover 444 includes a mover frame 452, a magnetic component 454, and a conductor component 456. Alternatively, the mover 444 can be designed with more or fewer components than that illustrated in FIG. 4A.

In this embodiment, the mover 444 is uniquely designed to move and position a device with improved accuracy. More specifically, in this embodiment, the mover 444 is a linear type motor that can be controlled by the control system 424 to generate independently controllable forces along a Y axis, along a Z axis, and about an X axis. This allows for the cancellation of undesired ripple in the forces along the Y axis, along the Z axis, and about the X axis (pitching disturbance); or the active generation of non-zero forces along the Y axis, along the Z axis, and/or about the X axis to accurately position the device.

The mover frame 452 supports the magnetic component 454 of the mover 444. In one embodiment, the mover frame 452 is generally rigid and shaped somewhat similar to a sideways “U”. For example, the mover frame 452 can be made of a highly magnetically permeable material, such as a soft iron that provides some shielding of the magnetic fields, as well as providing a low reluctance magnetic flux return path for the magnetic fields of the magnetic component 454.

In one embodiment, the mover frame 452 is secured to the stage base 236 (illustrated in FIG. 2A) or a reaction type assembly. In this embodiment, the conductor component 456 is secured to the connector bar 248 (illustrated in FIG. 2A) and moves relative to the magnetic component 454. Alternatively, for example, the conductor component 456 can be secured to the stage base 236, the magnetic component 454 can be secured to the connector bar 248, and the magnetic component 454 can be moved relative to the conductor component 456.

The magnetic component 454 is surrounded by a magnetic field. In FIG. 4A, the magnetic component 454 includes an upper magnet array 454A and a lower magnet array 454B. Further, in FIG. 4A, the magnet arrays 454A, 454B are secured to opposite sides of the mover frame 452, and a magnet gap 454C separates the magnet arrays 454A, 454B. Each of the magnet arrays 454A, 454B includes one or more magnets 454D. The design, the positioning, and the number of magnets 454D in each magnet array 454A, 454B can be varied to suit the design requirements of the mover 444. In FIG. 4A, each magnet array 454A, 454B includes a plurality of spaced apart, rectangular shaped magnets 454D that are spaced apart and aligned linearly. Further, in FIG. 4A, the magnets 454D in each magnet array 454A, 454B are orientated so that the poles facing the magnet gap 454C alternate between the North pole, and the South pole. Alternatively, each magnet array 454A, 454B can be designed so that the poles facing the magnet gap 454C alternate between the North pole, transversely oriented, and the South pole. This type of array is commonly referred to as a Halbach array.

Typically, each magnet array 454A, 454B is much longer along the major axis of movement (the Y axis in FIG. 4A) for a linear motor in which the conductor component 456 moves relative to the magnetic component 454.

In FIG. 4A, the polarity of the pole facing the magnet gap 454C of each of the magnets 454D in the upper magnet array 454A is opposite from the polarity of the pole of the corresponding magnet 454D in the lower magnet array 454B. Thus, North poles face South poles across the magnet gap 454C. This leads to strong magnetic fields in the magnet gap 454C and strong force generation capability.

It should be noted that the distance from North pole to North pole along the Y axis is considered to be 360 degrees.

Each of the magnets 454D can be made of a high energy product, rare earth, permanent magnetic material such as NdFeB. Alternately, for example, each magnet 454D can be made of a low energy product, ceramic or other type of material that is surrounded by a magnetic field.

A portion of the magnetic fields that surround the magnets 454D are illustrated in FIG. 4A are represented as arrows. In this embodiment, the magnetic component 454 includes Z axis magnetic flux 458 (illustrated as dashed arrows) that is oriented vertically along the Z axis across the magnetic gap 454C, and Y axis magnetic flux 460 (illustrated as dashed arrows) that is oriented substantially horizontally along the Y axis. The Y axis magnetic flux 460 can be separated into an upper, Y magnetic flux 460A that is adjacent the upper magnet array 454A and a lower Y magnetic flux 460B that is adjacent the lower magnet array 454B.

The conductor component 456 is positioned near and interacts with the magnet component 454, and is positioned and moves within the magnetic gap 454C.

The design of the conductor component 456 can vary pursuant to the teachings provided herein. In the embodiment illustrated in FIG. 4A, the conductor component 456 includes a plurality of conductors 456A (e.g. coils) that are arranged in a first array 456B of conductors 456A, and a second array 456C of conductors 456A that are positioned adjacent to first array 456B. In this embodiment, the arrays 456B, 456C are stacked along the Z axis, and the arrays 456B, 456C are fixedly secured together so that the first array 456B and the second array 456C move concurrently. Additionally, the conductor component 456 can include a conductor housing (not shown) which fixedly retains the conductors 456A together. For example, the arrays 456B, 456C can be embedded in the conductor housing.

The number of conductors 456A in each array 456B, 456C can vary to achieve the movement requirements of the mover 444. For simplicity, each array 456B, 456C is illustrated as including three conductors 456A. Alternatively, each array 456B, 456C can be designed with more or fewer than three conductors 456A. Further, the conductors 456A in each array 456B, 456C are aligned side by side along the Y axis.

In FIG. 4A, the three conductors 456A of the first array 456B are labeled U1 (illustrated with “/”), V1 (illustrated with “X”), and W1 (illustrated with “\”), respectively, while the three conductors 456A of the second array 456C are labeled U2 (illustrated with “/”), V2 (illustrated with “X”), and W2 (illustrated with “\”).

In certain embodiments, the arrays 456B, 456C are shifted (represented by “ΔP” in FIG. 4A) relative to the each other along the Y axis. As a result of this design, the mover 444 can better be controlled to provide a controllable force about the X axis. In FIG. 4A, the second array 456C is shifted in the positive direction (left to right in FIG. 4A) along the Y axis relative to the first array 456A. In this embodiment, U1 is positioned above and partly stacked on U2; V1 is positioned above and partly stacked on U2 and V2; and W1 is positioned above and partly stacked on V2 and W2. Alternatively, the second array 456C can be shifted in the negative direction (right to left in FIG. 4A) along the Y axis relative to the first array 456A.

The amount of shift between the arrays 456B, 456C used in the conductor component 456 can be varied to achieve the desired control level for the arrays 456B, 456C. As used herein, the term “coil pitch” means the width of the coil along the Y axis, and is represented by “CP” in FIG. 4A. Typically, CP is 60 degrees, 120 degrees, 240 degrees, or 300 degrees. In FIG. 4A, the second array 456C is shifted (represented as “ΔP”) approximately ¼ of the coil pitch relative to the first array 456B. Stated in another fashion, in this example, if the coil pitch is 240 degrees, the second array 456C is shifted approximately sixty degrees relative to the first array 456B. Alternatively, the second array 456C can be shifted greater than or lesser than ¼ of the coil pitch (60 degrees for the common case of CP=240 degrees) relative to the first array 456A. For example, in an alternative non-exclusive embodiment, the second array 456C can be shifted at least approximately ⅓ of the coil pitch relative to the first array 456B. Stated in another fashion, the second array 456C can be shifted at least approximately 80 degrees relative to the first array 456B.

In this embodiment, the conductors 456A of the first array 456B are positioned substantially within the upper Y magnetic flux 460A, and the conductors 456A of the second array 456C are is positioned substantially within the lower Y magnetic flux 460B. With this design, the control system 424 can direct current to the conductor component 456 to interact with the magnetic fields that surround the magnet component 454 to generate (i) a Y driving force 463 (illustrated as a two headed arrow) along the Y axis that can move the conductor component 456 along the Y axis; (ii) a Z force 465 (illustrated as a two headed arrow) along the Z axis that acts on the conductor component 456 along the Z axis; and (iii) a theta X moment 467 (illustrated as a two headed arrow) that acts on the conductor component 456 about the X axis.

In this embodiment, each of the arrays 456B, 456C functions as a three phase, AC racetrack type motor. More specifically, the control system 424 independently directs and controls the current to each U1 conductor (U1 phase), each V1 conductor (V1 phase), each W1 conductor (W1 phase), each U2 conductor (U2 phase), each V2 conductor (V2 phase), and each W2 conductor (W2 phase). In this embodiment, the control system 424 controls the current to these conductors in different electrical phases to generate the independently controllable Y driving force 463, the independently controllable a Z force 465, and the independently controllable theta X moment 467.

In certain embodiments, the control system 424 directs to each of the conductors 456A a sum of sine wave for each of the desired and controlled Y driving force 463, the Z force 465, and the theta X moment 467. Using the appropriate commutation variables, the exact compensation technique can be applied to map the Y force 463, the Z force 465, and the theta X force 467. In certain embodiments, the mover 444 can be tested and mapped so that the control system 424 can be calibrated to direct the appropriate current to the conductors 456A.

The current to each conductor 456A is determined by two sets of equations: compensation and commutation. The commutation equation for each of the six phases is a sum of three sine waves, which substantially correspond with each of the Y force, Z force, and X moment. The input to the commutation equations is the amplitude of each sine wave (three numbers) and the stage Y position, and the output is the current to each of the six phases. The motor produces Y force, Z force, and X moment which are approximately proportional to the three commutation amplitudes (Iy, Iz, and Itx). Typically, however there are errors in each degree of freedom of one to three percent.

Using mapping and compensation techniques, the commutation amplitudes are adjusted slightly to substantially eliminate the force errors. If the behavior of the motor (what force is produced by each of Iy, Iz, and Itx) is known at each Y position, the compensated commutation amplitudes Iyc, Izc, and Itxc can be calculated to produce almost exactly the desired Y force, Z force, and X moment.

When electric currents flow in the conductors 456A, a Lorentz type force is generated in a direction mutually perpendicular to the direction of the wires of the conductors 456A and the magnetic fields in the magnetic gap 354C. If the current magnitudes and polarities are adjusted properly to the alternating polarity of the magnet fields in the magnetic gap 454C, the controllable Y driving force 463, the Z force 465, and the theta X moment 467 is generated.

FIG. 4B is a perspective view of the conductor component 456 and illustrates that the first array 456B is offset from the second array 456C.

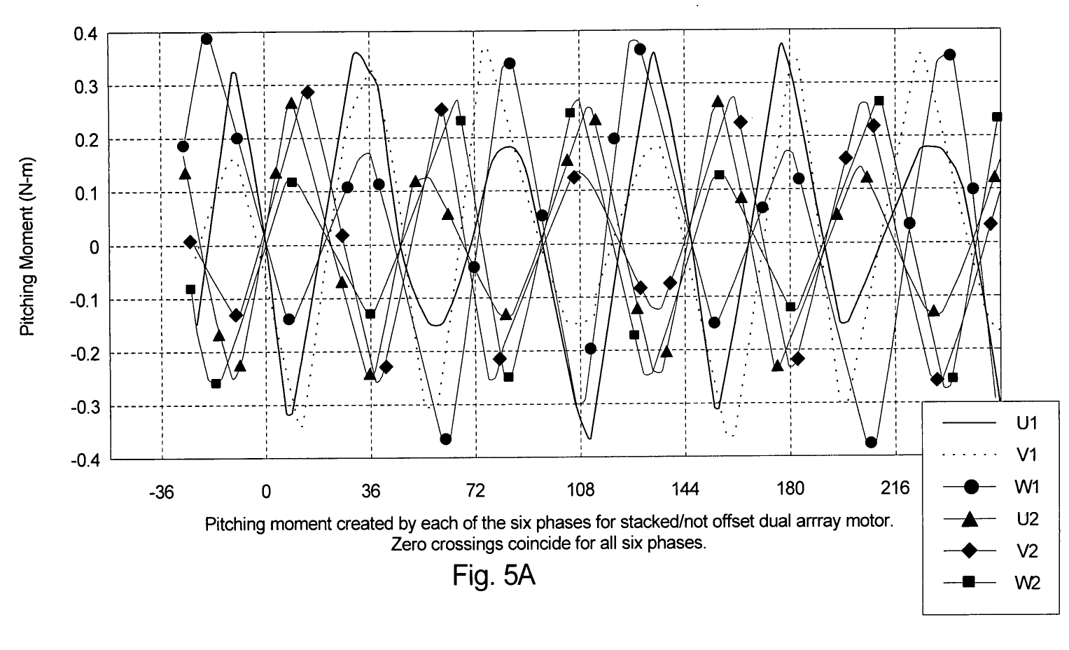

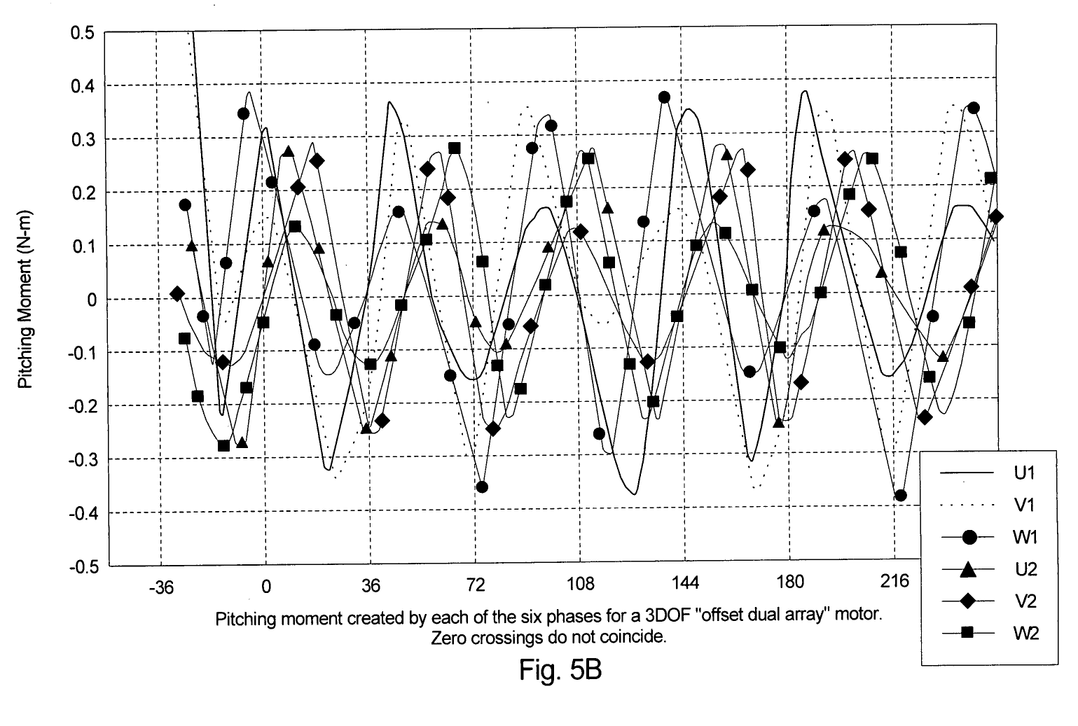

FIG. 5A is a chart that illustrates the pitching moment curves that can be created by the six phases of a mover that includes a first conductor array (conductors U1, V1, W1) and a second conductor array (conductors U2, V2, W2) positioned directly under the first conductor array. In this embodiment, the conductor arrays are not offset along the Y axis i.e., ΔP=0. An example of this design and control thereof is contained in U.S. Publication Number 2006/0232142. As far as permitted, the contents of U.S. Publication Number 2006/0232142 are incorporated herein by reference.

In this embodiment, FIG. 5A illustrates the pitch produced by a one ampere constant current being directed to each of the six conductors (U1, V1, W1, U2, V2, W2) relative to position of the conductor along the Y axis of the magnetic component. In this example, all six pitching moment curves (all phases) are approximately zero near the same point at approximately 24 millimeter intervals. Stated in another fashion, a locations −24, 0, 24, 48, 72, 96, 120, 144, 168, 192, 216, and 240 (along the Y movement axis), each of the conductors produces approximately zero pitching moment when one ampere constant current is being directed to the conductors. At these particular locations along the Y axis, because each of the conductors produces approximately zero pitching moment, it is difficult or impossible to produce a controlled pitching moment (torque about the X axis).

FIG. 5B is a chart that illustrates pitching moment curves that can be created by a mover 444 similar to that illustrated in FIG. 4A that includes a first conductor array 456B and a second conductor array 456C that are offset. More specifically, FIG. 5B illustrates the pitch produced by a one ampere constant current being directed to each of the six conductors U1, V1, W1, U2, V2, W2, (each of the six phases) relative to position of the magnetic component along the Y axis. In this example, there are not any points where all six pitch curves are nearly zero at the same place. Stated in another fashion, in this design, there are not any locations along the Y movement axis, that each of the conductors produces approximately zero pitching moment when one ampere constant current is being directed to the conductors. With this design, a linear combination of the six phase currents directed from the control system to the six phases can produce any desired pitching moment along the entire Y axis travel.

With this design, with the correct choice of commutation variables, the mover can produce independently controllable forces in three degrees of freedom.

It should be noted that the amount of shift of the coil pitch can be any amount that results in pitching moment curves that do not all cross zero at the same motor position.

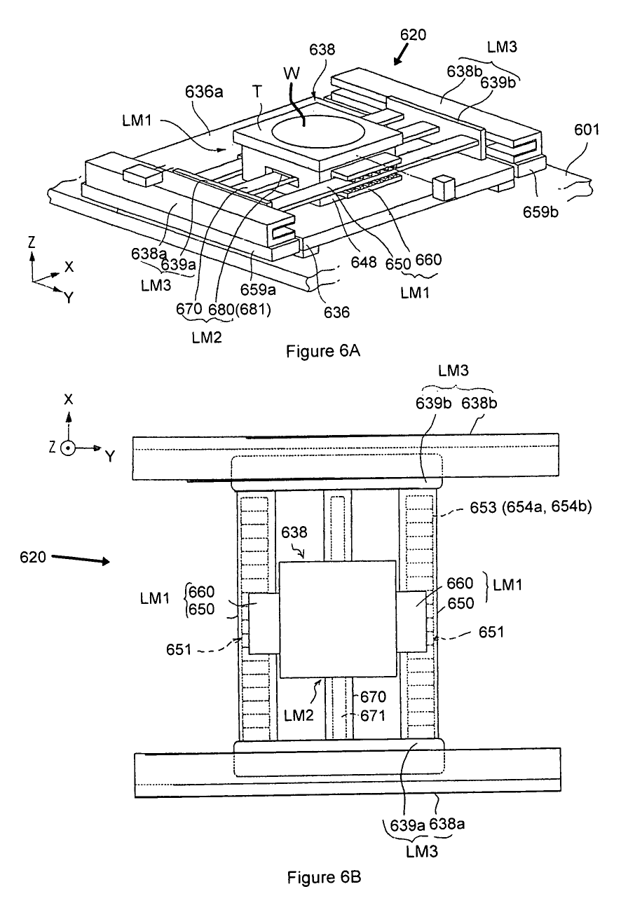

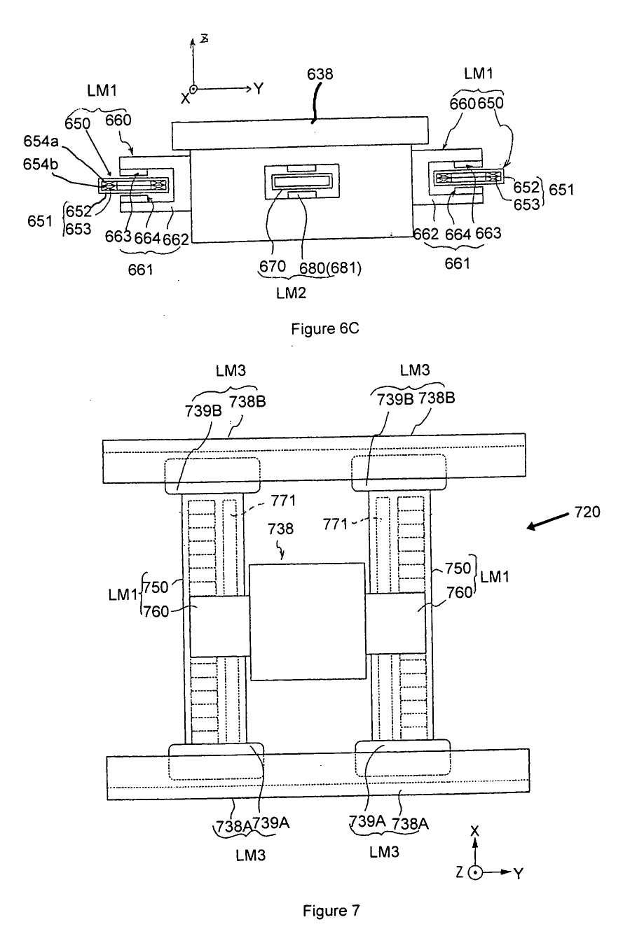

FIG. 6A is a perspective view and FIG. 6B is a top plan view another embodiment of a stage assembly 620. In this embodiment, the stage assembly 620 includes a stage 638, linear movers (drive apparatuses) LM1, which drive the stage 638 in the X axis direction, the Z axis direction and the theta Y direction about the Y axis, linear mover (second drive apparatus) LM2, which drives the stage 638 at a fine stroke in the Y axis direction, and linear movers (third drive apparatuses) LM3, which drive the stage 638 at a long stroke in the Y axis direction.

In one embodiment, the stage 638 comprises a table T, which holds the work piece W, and an XY stage 648, which is supported on a stage base 636 and moves along the movement plane 636A in unison with the table T. A load canceller mechanism (not shown in the drawings) is described in Japanese Patent Application No. 2004-215434 and its counterpart U.S. Patent Publication 2008/0013060 and is provided on this XY stage 648. This load canceller mechanism has a support part, which applies internal pressure to a bellows to support the stage 638, and an air bearing part, which causes the stage 638 to float with respect to the movement plane 636A in opposition with the movement plane 636A, which is a guide surface.

As illustrated in FIG. 6B, linear motors LM1 are provided at both sides in the X axis direction flanking the stage 638 separated by a distance, and they comprise stators 650 (magnetic component), which have coil units 651 (conductor component) to be discussed below and extend in the X axis direction, and movers 660, which are provided on the stage 638 and have magnet units 661 to be discussed below and illustrated in FIG. 6C.

FIG. 6C is a front view of the stage 638 and linear motors LM1 and LM2 as seen from a −X side. Magnet units (magnetic field generating apparatuses) 661 comprise a magnetic pole base 662, which is formed by a nonmagnetic body (for example, ceramics) whose end face shape is U-shaped and which extends in the X direction, a magnet array 663 arranged at one of (the upper side) the inner walls of the magnetic pole base 662, and a magnet array 664 arranged at another of (lower side) the inner walls.

In addition, by arranging the coil units 651 so as to fit into the concave parts of the magnet units 661 while separating the coil units 651 at a prescribed interval and applying an alternating voltage (current) to the coil units 651 by means of the control system 24 shown in FIG. 1, a driving force (Lorentz force) is generated between the coil units 651 and the magnet units 661, and the coil units 651 and the magnet units 661 move relatively in the thrust direction (here, the X axis direction).

Coil units (armature units) 651 comprise cans 652, which comprise nonmagnetic bodies and have a hollow rectangular shape, and a plurality of coil bodies 653 arrayed without gaps at a prescribed array period (CP) along the X axis direction at the interior of the cans. These coil bodies 653 are respectively formed in an approximately 0-shape (see FIG. 4B) and are arranged so as to have electric current paths that are parallel with the Y axis at the center part of the Y axis direction. In addition, the coil bodies 653 are respectively plurally arrayed along the X axis direction and form coil arrays 654A, 654B, which are superposed in the Z axis direction. In addition, these coil arrays 654A, 654B are superposed in a status in which they are shifted by a prescribed phase difference ΔP (as discussed above) in the X axis direction. Note that these coil arrays 654A, 654B are such that by hardening the surfaces using a resin, etc. to form single plate shapes and arranging by aligning in parallel leaving prescribed intervals from the inner walls of the cans 652, gaps are formed at the inner parts of the cans 652, and by causing a cooling medium to flow in these gaps, the heated coil bodies 653 are cooled.

Linear motor LM2 comprises a stator (second stator) 670, which has a coil unit 671 (see FIG. 6B) and which is provided by inserting into the stage 638 (XY stage 648) and extends in the X axis direction, and a mover (second mover) 680, which has magnet units 681 (see FIGS. 6A and 6C) and is provided (connected) on the stage 638 (XY stage 648). The magnet unit 681, in a manner similar to magnet arrays 663 and 664, has a configuration such that the plurality of magnets are arrayed in the X axis direction at prescribed intervals are respectively arranged in opposition at both surfaces of the mover 680. The coil unit 671 is arranged so as to have an electric current path that is parallel with the X axis at the center part of the X axis direction, and by alternating voltage (current) being applied by means of the control apparatus CONT, a driving force (Lorentz force) is generated between the coil unit 671 and the magnet unit 681, and the coil unit 671 and the magnet unit 681 move relatively by a slight amount in the thrust direction (here, the Y axis direction).

Linear motors LM3 comprise Y axis stators 638a and 638b, which extend in the Y direction, and movers 639a and 369b, which are respectively inserted between these stators 638a, 638b from the inner side. Movers 639a and 639b have coil units (not shown in the drawings) arrayed in the Y axis direction in a configuration similar to that of coil units 651 of stators 650 in linear motors LM1. These movers 639a, 639b are supported in unison at both ends of stators 650 in linear motors LM1 and stator 670 of linear motor LM2 and move in the Y axis direction in unison with these stators 650, 670.

In addition, stators 638A and 638B also have magnet arrays (not shown in the drawings) which are arrayed in the Y axis direction in a configuration similar to that of magnet arrays 663 and 664 of movers 660 of linear motors LM1. In addition, by applying an alternating voltage (current) to the coil units by means of control system, a driving force (Lorentz force) is generated between the coil units and the magnet arrays, and stators 638a and 638b move relative to movers 639a and 639b in the thrust direction (here, the Y axis direction).

Stators 638a and 638b are arranged on protruding parts 659a and 659b, which are provided on a base part 601 in the vicinity of the end parts of one side and the other side of the X direction to protrude upward with the Y direction as the lengthwise direction. These Y axis stators 638a, 638b are supported in a floating manner with a prescribed clearance above the protruding parts 659a, 659b via gas static pressure bearings, for example, air bearings, that are not shown in the drawings and are provided at the respective lower surfaces thereof. This is because, due to the reaction force generated by movement of the stage 638 in the Y direction, stators 638a and 638b move in the opposite direction as a Y direction Y counter mass to offset this reaction force according to the law of conservation of momentum.

In a case where linear motor LM1 is used alone, it is possible to produce a driving force that moves the stage 638 in the X direction, the Z direction and the θY direction, and by providing linear motors LM1 at both sides of the stage 638 and driving them independently, it is possible to produce a driving force that moves the stage 638 in the θZ direction and the θX direction, and it becomes possible to drive the stage 638 with five degrees of freedom.

For example, by directing current with the control system to the linear movers LM1, it is possible to move the stage 638 with five degrees of freedom, namely the X direction, Z direction, θY direction, θZ direction and θX direction. More specifically, this movement can be accomplished by adjusting the electric current supplied to the respective coil bodies 653 so that the direction and amplitude of the electric current component for X axis driving become the preferred X axis driving force and by adjusting the electric current component for Z axis driving so that it becomes the preferred Z axis driving force.

In addition, by moving the stage 638 at a long stroke using linear motors LM3 while moving the stage 638 a slight amount at a short stroke using linear motor LM2, it is possible to drive the wafer stage 638 with six degrees of freedom in conjunction with the driving of linear motors LM1.

In this way, in the present embodiment, by using linear motor LM1, it is possible to move the stage 638 with the five degrees of freedom, namely of the X direction, Z direction, θY direction, θZ direction and θX direction, and it is possible to avoid large increases in costs such as those in the case in which actuators are provided in the respective directions while it is also possible to control the movement of the stage 638 with high accuracy in a plurality of directions.

In addition, in the present embodiment, since coil arrays 654A and 654B are superposed having a phase difference in the X axis direction, it is possible to reliably control the position of the stage 638 in the θY direction without the pitching moment Ty becoming zero.

Another embodiment of the stage assembly 720 is illustrated in FIG. 7. In the present embodiment, coil units 771 that comprise the linear motor for fine amount movement in the Y direction (linear motor LM2 of the previous embodiment) are respectively provided on stators 750. Also, magnet units (not shown in FIG. 7) that oppose these coil units 771 are provided on the movers 760. In addition, movers 739a and 739b of linear motors LM3, to which the respective stators 750 are connected, are provided at both sides of the Y direction of the stage 738 to share stators 738a and 738b and mutually independently freely move.

In this embodiment, in addition to the fact that the same actions and effects as the above embodiments can be obtained, it is not necessary to separately provide the stator and movers of a linear motor for Y fine movement, and it is possible to contribute to making the apparatus more compact, lighter in weight and lower in cost. Particularly, in the present embodiment, by making the weight lighter, it is possible to reduce the amount of heat when the stage 738 is driven, it is possible to restrict the occurrence of causes of decreases in accuracy, for example, air turbulence, and it is also possible to improve work piece positioning accuracy and the accuracy of pattern transfer to the wafer W.

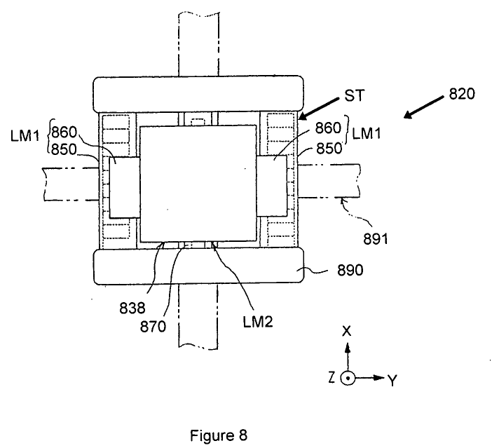

FIG. 8 illustrates another embodiment of a stage assembly 820. In this embodiment, linear motors LM1 and LM2 are used as the drive apparatuses for stage 838 fine movement, and a drive apparatus for rough movement is separately provided.

Specifically, stators 850 and 870 of linear motors LM1 and LM2 are supported at both ends by support parts 890 that respectively extend in the Y axis direction. The stators 850 interact with moving component 860. In addition, a stage unit ST comprising the wafer stage 838, linear motors LM1 and LM2, and the support parts 890 functions as a fine movement stage, and the wafer stage 838 is capable of slight movement with six degrees of freedom in the Y direction, X direction, Z direction, θY direction, θZ direction, and θX direction by means of the driving forces of linear motors LM1 and LM2.

Also, this stage unit ST is connected to an XY rough movement stage 891 and is able to freely move at a long stroke in the Y direction and the X direction along the movement plane.

With the present embodiment, it is possible to perform fine movement of the wafer stage 838 with six degrees of freedom without causing cost increases, and it is possible to adjust position and the attitude with high accuracy.

In addition, the present invention can be applied to a so-called liquid immersion exposure apparatus that locally fills liquid between the projection optical system and the substrate and exposes the substrate via the liquid, but there are also disclosures with respect to liquid immersion exposure apparatuses in the International Patent Publication No. 99/49504 pamphlet. In addition, the present invention may also be applied to a liquid immersion exposure apparatus that performs exposure in a status in which the entire surface of the substrate to be exposed is immersed in the liquid, such as those disclosed in Japanese Unexamined Patent Application Publication No. H6-124873, Japanese

Unexamined Patent Application Publication No. H10-303114, and U.S. Pat. No. 5,825,043.

In addition, in the respective embodiments discussed above, an explanation was made giving an example of an exposure apparatus that comprises an optical assembly 16, but it is possible to apply the present invention to an exposure apparatus and an exposure method that does not use an optical assembly 16. In this way, even in the case in which an optical assembly 16 is not used, exposure light is irradiated to the substrate via an optical member such as a lens, and a liquid immersion space is formed in a prescribed space between such an optical member and the substrate.

In addition, the present invention can also be applied to twin-stage type exposure apparatuses in which a plurality of substrate stages (wafer stages) are provided. The structure and the exposure operations of twin-stage type exposure apparatuses are disclosed in, for example, Japanese Unexamined Patent Application Publication No. 10-163099, Japanese Unexamined Patent Application Publication No. 10-214783 (corresponds to U.S. Pat. Nos. 6,341,007, 6,400,441, 6,549,269 and 6,590,634), Tokuhyo No. 2000-505958 (corresponds to U.S. Pat. No. 5,969,441) and U.S. Pat. No. 6,208,407. In addition, the present invention may also be applied to the wafer stage of Patent Application No. 2004-168481 previously applied for by the applicants of the present application.

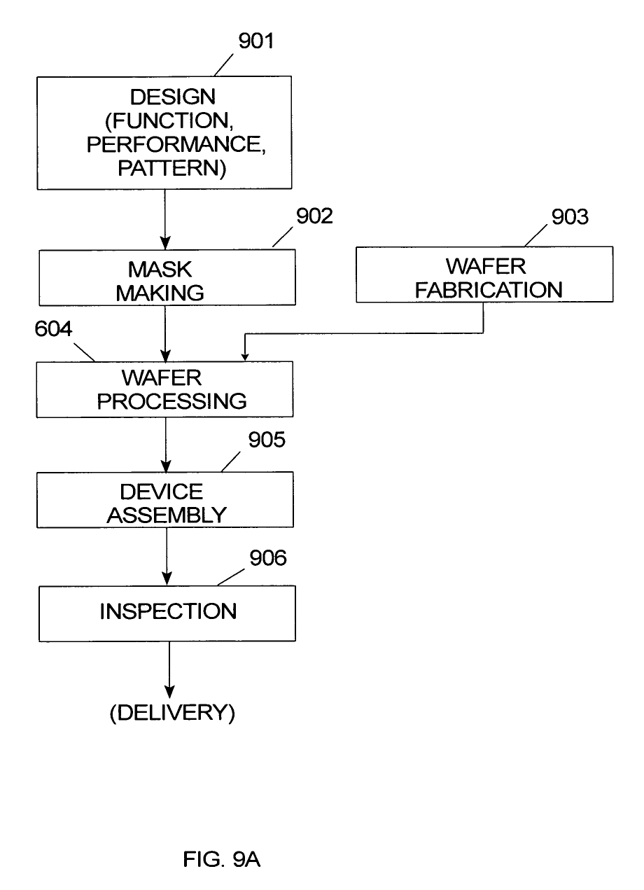

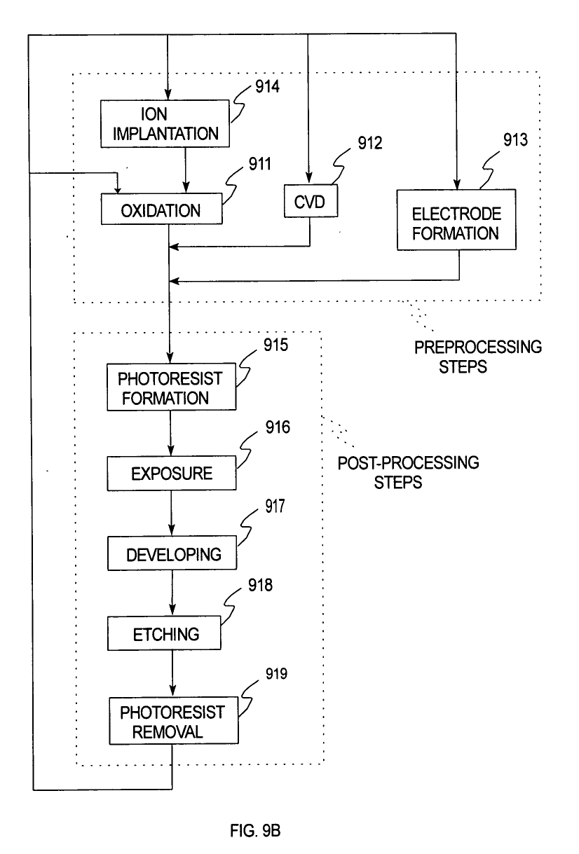

Semiconductor devices can be fabricated using the above described systems, by the process shown generally in FIG. 9A. In step 901 the device's function and performance characteristics are designed. Next, in step 902, a mask (reticle) having a pattern is designed according to the previous designing step, and in a parallel step 903 a wafer is made from a silicon material. The mask pattern designed in step 902 is exposed onto the wafer from step 903 in step 904 by a photolithography system described hereinabove in accordance with the present invention. In step 9605, the semiconductor device is assembled (including the dicing process, bonding process and packaging process), finally, the device is then inspected in step 906.

FIG. 9B illustrates a detailed flowchart example of the above-mentioned step 904 in the case of fabricating semiconductor devices. In FIG. 9B, in step 9611 (oxidation step), the wafer surface is oxidized. In step 912 (CVD step), an insulation film is formed on the wafer surface. In step 913 (electrode formation step), electrodes are formed on the wafer by vapor deposition. In step 914 (ion implantation step), ions are implanted in the wafer. The above mentioned steps 911-914 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 915 (photoresist formation step), photoresist is applied to a wafer. Next, in step 916 (exposure step), the above-mentioned exposure device is used to transfer the circuit pattern of a mask (reticle) to a wafer. Then in step 917 (developing step), the exposed wafer is developed, and in step 918 (etching step), parts other than residual photoresist (exposed material surface) are removed by etching. In step 919 (photoresist removal step), unnecessary photoresist remaining after etching is removed. Multiple circuit patterns are formed by repetition of these preprocessing and post-processing steps.

It is to be understood that movers disclosed herein are merely illustrative of the presently preferred embodiments of the invention and that no limitations are intended to the details of construction or design herein shown other than as described in the appended claims.

What is claimed is:

1. A mover for moving a stage along a first axis, the mover comprising:
a magnetic component including a plurality of magnets that are surrounded by a magnetic field; and
a conductor component that is positioned near the magnetic component in the magnetic field, the conductor component interacting with the magnetic component when current is directed to the conductor component to generate a controlled force along the first axis, and a controllable moment about a second axis that is perpendicular to the first axis.

2. The mover of claim 1 wherein the conductor component interacts with the magnetic component to generate a controlled force along a third axis that is perpendicular to the first axis and the second axis when current is directed to the conductor component.

3. The mover of claim 1 wherein the conductor component includes a first array of conductors and a second array of conductors that are positioned adjacent to the first array along a third axis that is perpendicular to the first axis, wherein the first array is shifted relative to the second array along the first axis.

4. The mover of claim 3 wherein each of the conductors has a coil pitch, and wherein the first array is shifted approximately one quarter of a coil pitch along the first axis from the second array.

5. The mover of claim 3 wherein each of the conductors has a coil pitch, and wherein the first array is shifted along the first axis relative to the second array sufficiently so that the pitching moment curves that result from directing a constant current to the conductors while having relative movement between the conductor component and the magnet component do not all cross zero at the same position.

6. A mover of claim 1 wherein the magnetic component includes a first magnetic array and a second magnetic array that are positioned on opposite sides of the conductor component.

7. A stage assembly that moves a device, the stage assembly including a stage that retains the device and the mover of claim 1 that moves the stage along the first axis.

8. The stage assembly of claim 7 further comprising a guide surface that supports the stage, and wherein the first axis and the second axis are parallel to the guide surface.

9. An exposure apparatus including an illumination system and the stage assembly of claim 7 that moves the stage relative to the illumination system.

10. A process for manufacturing a device that includes the steps of providing a substrate and forming an image to the substrate with the exposure apparatus of claim 9.

11. A mover for moving a stage along a first axis, the mover comprising:
a magnetic component including a plurality of magnets that are surrounded by a magnetic field;
a conductor component that is positioned near the magnetic component, the conductor component including a first array of conductors and a second array of conductors that are positioned adjacent to the first array along a second axis that is perpendicular to the first axis, the arrays being secured together; wherein the first array is shifted relative to the second array along the first axis; and wherein the conductor component interacts with the magnetic component when current is directed to the conductor component to generate a controlled force along the first axis; and
a control system that directs current to the conductor component to generate the controlled force along the first axis.

12. The mover of claim 11 wherein the conductor component interacts with the magnetic component when current is directed to the conductor component to generate a controlled force about a third axis that is perpendicular to the first axis.

13. The mover of claim 11 wherein the conductor component interacts with the magnetic component to generate a controlled force along second axis when current is directed to the conductor component.

14. The mover of claim 11 wherein each of the conductors has a coil pitch, and wherein the first array is shifted approximately one quarter of a coil pitch along the first axis from the second array.

15. The mover of claim 11 wherein each of the conductors has a coil pitch, and wherein the first array is shifted along the first axis relative to the second array sufficiently so that the pitching moment curves that result from directing a constant current to the conductors while having relative movement between the conductor component and the magnet component do not all cross zero at the same position.

16. The mover of claim 11 wherein the magnetic component defines a magnetic gap and wherein the conductor component is positioned in the magnetic gap.

17. A stage assembly that moves a device, the stage assembly including a stage that retains the device and the mover of claim 11 that moves the stage along the first axis.

18. An exposure apparatus including an illumination system and the stage assembly of claim 17 that moves the stage relative to the illumination system.

19. A process for manufacturing a device that includes the steps of providing a substrate and forming an image to the substrate with the exposure apparatus of claim 18.

20. A method for moving a device along a first axis, the method comprising the steps of:
coupling the device to a stage;
providing a magnetic component having a plurality of magnets that are surrounded by a magnetic field;
providing a conductor component that is positioned near the magnetic component in the magnetic field;
coupling one of the components to the stage; and
directing current to the conductor component so that the conductor component interacts with the magnetic component to generate a controlled force along the first axis, and a controlled moment about a second axis that is perpendicular to the first axis.

21. The method of claim 20 wherein the step of directing current includes the conductor component interacting with the magnetic component to generate a controlled force along a third axis that is perpendicular to the first axis and the second axis.

22. The method of claim 20 wherein the step of providing a conductor component includes providing a first array of conductors, and a second array of conductors that are positioned adjacent to the first array along a third axis that is perpendicular to the first axis, wherein the first array is shifted relative to the second array along the first axis.

23. The method of claim 22 wherein each of the conductors has a coil pitch, and wherein the first array is shifted approximately one quarter of a coil pitch along the first axis from the second array.

24. A method of claim 20 wherein the step of providing a magnetic component includes providing a first magnetic array and a second magnetic array that are positioned on opposite sides of a magnetic gap that contains the conductor array.

25. A method for making an exposure apparatus comprising the steps of providing an illumination source, providing a device, and moving the device by the method of claim 20.

26. A method of making a wafer including the steps of providing a substrate and forming an image on the substrate with the exposure apparatus made by the method of claim 25.
